(19) United States
(12) Patent Application Publication
(10) Pub. No.: US 2022/0130666 A1
(43) Pub. Date: Apr. 28, 2022

(54) SEMICONDUCTOR DEVICE MANUFACTURING METHOD AND HOT PLATE

(71) Applicant: FUJI ELECTRIC CO., LTD., Kawasaki-shi (JP)

(72) Inventors: Kohichi HASHIMOTO, Kawasaki-shi (JP); Shunsuke TANAKA, Kawasaki-shi (JP); Yuya TAKAHASHI, Kawasaki-shi (JP)

(73) Assignee: FUJI ELECTRIC CO., LTD., Kawasaki-shi (JP)

(21) Appl. No.: 17/464,441

(22) Filed: Sep. 1, 2021

(30) Foreign Application Priority Data
Oct. 26, 2020 (JP) 2020-178708

(51) Int. Cl. H01L 21/02; H01L 21/67; H01L 21/288; H01L 21/304

(52) U.S. Cl. CPC H01L 21/02318; H01L 21/67103; H01L 21/304; H01L 21/288; H01L 21/02035

(57) ABSTRACT

A semiconductor device manufacturing method includes forming a ring-shaped rib at an outer circumferential edge of a semiconductor wafer by grinding a center of a back surface of the semiconductor wafer, so that the rib has a thickness greater than a thickness of the center of the semiconductor wafer, pasting a first protective film on the back surface of the semiconductor wafer, pasting a second protective film so as to cover an outer circumferential edge of the first protective film and an outer circumference of the rib, positioning the back surface of the semiconductor wafer so as to face a heating surface of a hot plate and directly heating the first protective film and the second protective film by using the hot plate, and performing a plating treatment on a surface of the semiconductor wafer.

### CROSS REFERENCE TO RELATED APPLICATIONS

This application is based upon and claims the benefit of priority of the prior Japanese Patent Application No. 2020-178708, filed on Oct. 26, 2020, the entire contents of which are incorporated herein by reference.

### BACKGROUND OF THE INVENTION

### Field of the Invention

The present invention relates to a semiconductor device manufacturing method and a hot plate.

### Description of the Related Art

A semiconductor device has a substrate having thereon a semiconductor element such as an insulated gate bipolar transistor (IGBT), a power metal oxide semiconductor field effect transistor (MOSFET) and a free wheeling diode (FWD), and is utilized in, for example, an inverter apparatus.

In a method for manufacturing this type of semiconductor device, a plating treatment is performed on one main surface side (front surface side) of a semiconductor wafer to form a plated layer (see Japanese Patent Laid-Open No. 2016-152317, for example). According to Japanese Patent Laid-Open No. 2016-152317, before the plating treatment, a protective film is formed on a part where the plated layer is not to be formed. More specifically, in Japanese Patent Laid-Open No. 2016-152317, a first film is pasted on the other main surface side (back surface side) of the semiconductor wafer, and a second film is pasted on an outer circumferential part of the semiconductor wafer.

In the step where films are pasted, bubbles may be formed between the semiconductor wafer and the films. In the subsequent plating treatment, the semiconductor wafer is exposed to a relatively high temperature environment. Thus, when the bubbles are enlarged because of the temperature, the bubbles become a pathway of entry of a plating solution. As a result, a plated layer is formed in an unnecessary part, and it is conceivable that a semiconductor wafer that has unpreferable appearance is formed.

Accordingly, it has been conventionally proposed that, after a film is pasted on a semiconductor wafer and before a plating treatment is performed, the film is heated to improve adherence between the film and the semiconductor wafer (see Japanese Patent Laid-Open No. 2011-222898, for example).

By the way, in order to heat a semiconductor wafer on which a film is pasted, a plurality of semiconductor wafers are accommodated within a box-shaped cassette, and the cassette is inserted to a batch oven furnace. Thus, the plurality of semiconductor wafers can be heated by one operation.

However, in the batch oven furnace, uneven in-furnace temperatures easily occur because the in-furnace space is large. Also, time is required until a stable in-furnace temperature is acquired, which possibly has an influence on the throughput of the manufacturing apparatus. If the semiconductor wafers have a large diameter, a problem of difficult automatic transfer of the cassette may also occur.

The present invention has been made in view of such points, and it is one of objects to provide a semiconductor device manufacturing method and a hot plate which can improve adhesion of a protective film to a semiconductor wafer and can improve a throughput.

### SUMMARY OF THE INVENTION

A semiconductor device manufacturing method according to one aspect of the present invention includes a rib forming step of forming a ring-shaped rib at an outer circumferential edge of a semiconductor wafer by grinding a center of a back surface of the semiconductor wafer, the rib having a larger thickness than a thickness of the center of the semiconductor wafer, a back-surface film pasting step of pasting a first protective film on the back surface of the semiconductor wafer, an outer-circumference film pasting step of pasting a second protective film so as to cover an outer circumferential edge of the first protective film and an outer circumference of the rib, a heating step of positioning the back surface of the semiconductor wafer so as to face a heating surface of a hot plate and directly heating the first protective film and the second protective film by using the hot plate, and a plating step of performing a plating treatment on a surface of the semiconductor wafer.

A hot plate according to one aspect of the present invention is a hot plate that heats a first protective film and a second protective film, the first protective film and second protective film being pasted on a semiconductor wafer, wherein the semiconductor wafer has a ring-shaped rib at an outer circumferential edge of the semiconductor wafer, the rib is formed by grinding a center of a back surface of the semiconductor wafer, and the rib has a larger thickness than a thickness of the center of the semiconductor wafer, the first protective film is pasted on the back surface of the semiconductor wafer, the second protective film is pasted so as to cover an outer circumferential edge of the first protective film and an outer circumference of the rib, and the hot plate has a heating surface, the back surface of the semiconductor wafer is positioned so as to face the heating surface, and the heating surface directly heats the first protective film and the second protective film.

### Advantageous Effect of Invention

According to the present invention, adhesion of a protective film to a semiconductor wafer can be improved, and a throughput can be improved.

### BRIEF DESCRIPTION OF THE DRAWINGS

FIG. 1 is a cross-sectional view of a semiconductor wafer according to an embodiment;

FIG. 2 is a partially enlarged view of the semiconductor wafer shown in FIG. 1;

FIG. 3 is a cross-sectional view of a semiconductor manufacturing apparatus (oven furnace) according to a comparison example;

FIG. 4 is a plan view from above a semiconductor manufacturing apparatus according to the embodiment;

FIG. 5 is a cross-sectional view of the semiconductor manufacturing apparatus shown in FIG. 4;

FIG. 6 is a flowchart showing an example of a semiconductor device manufacturing method according to the embodiment;

FIG. 7 is a schematic diagram showing one step example of the semiconductor device manufacturing method of the embodiment;

FIG. 8 is a schematic diagram showing one step example of the semiconductor device manufacturing method of the embodiment;

FIG. 9 is a schematic diagram showing one step example of the semiconductor device manufacturing method of the embodiment;

FIG. 10 is a schematic diagram showing one step example of the semiconductor device manufacturing method of the embodiment;

FIGS. 11A to 11C are schematic diagrams showing one step example of the semiconductor device manufacturing method of the embodiment;

FIG. 12 is a schematic diagram showing one step example of the semiconductor device manufacturing method of the embodiment;

FIG. 13 is a graph showing temporal change of the temperature in a protective-film heating step;

FIG. 14 is a schematic diagram of a hot plate according to a variation example;

FIG. 15 is a schematic diagram of a hot plate according to another variation example;

FIG. 16 is a schematic diagram of a hot plate according to another variation example;

FIG. 17 is a plan view of a hot plate according to another variation example;

FIG. 18 is a cross-sectional view taken at line A-A in FIG. 17; and

FIG. 19 is a plan view of a hot plate according to another variation example.

### DETAILED DESCRIPTION OF THE PREFERRED EMBODIMENT

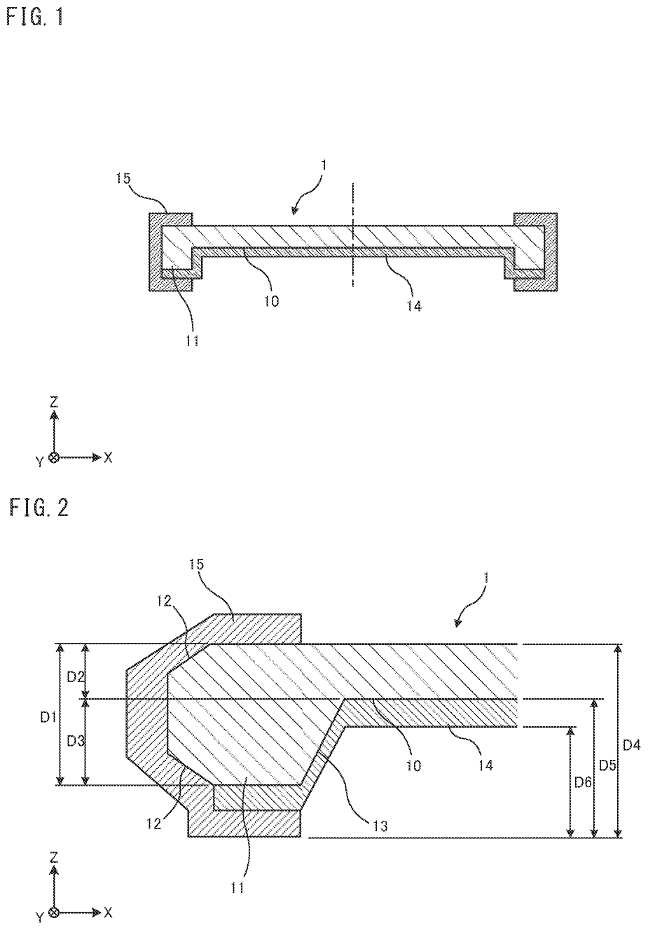

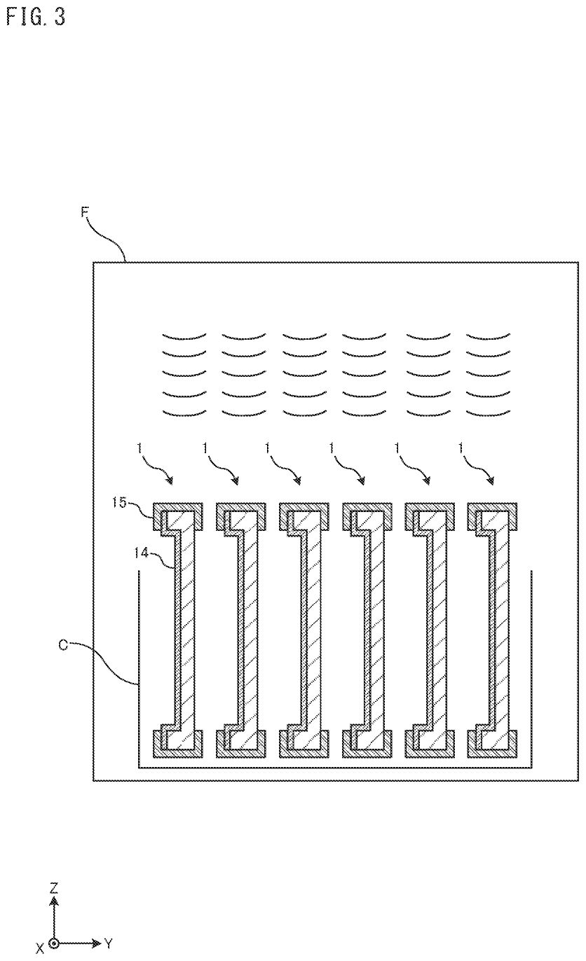

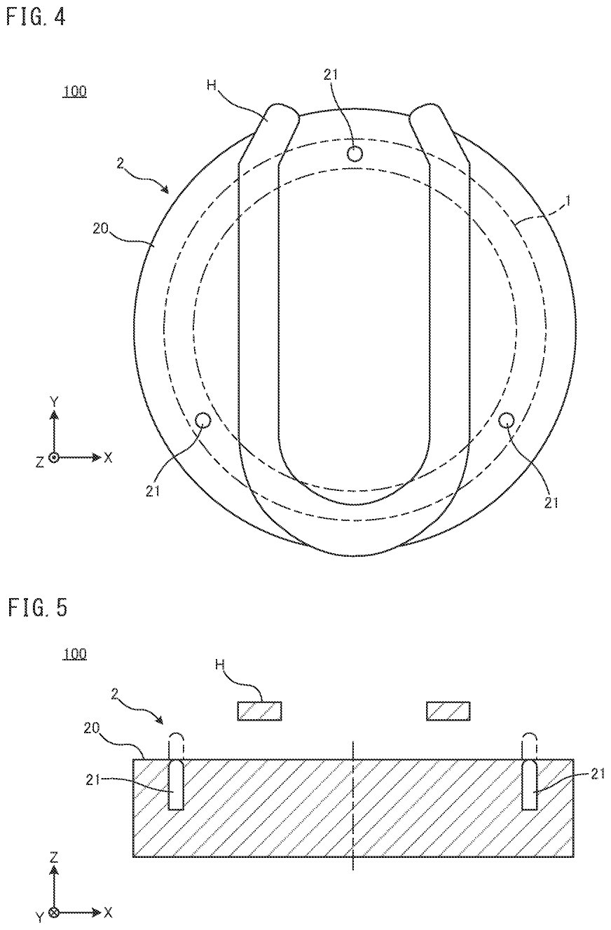

A semiconductor manufacturing apparatus and a semiconductor device manufacturing method to which the present invention is applicable are described below. FIG. 1 is a cross-sectional view of a semiconductor wafer according to an embodiment. FIG. 2 is a partially enlarged view of the semiconductor wafer shown in FIG. 1. FIG. 3 is a cross-sectional view of a semiconductor manufacturing apparatus (oven furnace) according to a comparison example. FIG. 4 is a plan view from above a semiconductor manufacturing apparatus according to the embodiment. FIG. 5 is a cross-sectional view of the semiconductor manufacturing apparatus shown in FIG. 4. It should be noted that the semiconductor manufacturing apparatus and semiconductor device manufacturing method which are described below are merely examples and can be changed as required without limiting thereto.

In the following drawings, a right-left direction of the semiconductor manufacturing apparatus, a front-back direction of the semiconductor manufacturing apparatus and a height direction of the semiconductor manufacturing apparatus (thickness direction of a semiconductor wafer) are defined as an X direction, a Y direction and a Z direction, respectively. The shown X, Y, Z axes are orthogonal to each other and form a right-handed system. In some cases, the Z direction may be called a top-bottom direction. These directions (front-back, right-left, and top-bottom directions) are words used for convenience of description, and the correspondence relationships with the X, Y, Z directions may change in accordance with the attitude of the semiconductor device (semiconductor wafer). The expression “plan view” herein refers to a view from above the semiconductor manufacturing apparatus.

A semiconductor manufacturing apparatus 100 (see FIG. 4 and FIG. 5) according to the embodiment forms a plurality of devices (semiconductor devices) in a semiconductor wafer 1 and divides the semiconductor wafer 1 to individual chips. The semiconductor devices according to the embodiment are applied to a power converter such as a power control unit and are power semiconductor modules included in an inverter circuit. The semiconductor manufacturing apparatus 100 according to the embodiment is an apparatus for implementing one step in a semiconductor device manufacturing method. Therefore, details of other steps included in the semiconductor device manufacturing method are omitted where appropriate, and the step specific to the present invention (heating step, which is described below) is mainly described. The same is true for the configuration of the semiconductor manufacturing apparatus 100, and description of the apparatus configuration not directly related to the present invention is omitted where appropriate.

First, the semiconductor wafer 1 to be processed is described. As shown in FIG. 1 and FIG. 2, the semiconductor wafer 1 is formed to have a disk shape having a predetermined thickness by a semiconductor substrate of, for example, silicon (Si), silicon carbide (SiC), gallium nitride (GaN) or diamond. A predetermined treatment is performed on a surface of the semiconductor wafer 1 so that devices (not shown) are formed on regions divided by division planning lines in grid. The devices are formed mainly in a central region of the semiconductor wafer 1. Thus, a ring-shaped surplus region (not shown) with no devices is formed in an outer circumferential part of the semiconductor wafer 1. A notch, for example, (not shown) indicating a crystal orientation is provided at a predetermined position at an outer edge of the semiconductor wafer 1.

The semiconductor wafer 1 according to the embodiment has a circular concave portion 10 formed by grinding processing, and an outer circumferential edge of the back surface of the semiconductor wafer 1 thus has a so-called rib shape having a ring-shaped rib 11 that is thicker than the central part. The concave portion 10 is provided in the aforementioned central region (not shown) of the semiconductor wafer 1. The rib 11 is provided in the aforementioned surplus region (not shown) of the semiconductor wafer 1.

More specifically, as shown in FIG. 2, the outer circumferential edge part of the semiconductor wafer 1 has a chamfered portion 12 at its upper surface and lower surface. An inner surface of the concave portion 10, that is, an inner surface of the rib 11 is a tilting surface 13 that tilts toward radial outside as it goes downward. With the rib-shaped wafer, the strength can be maintained because of the ring-shaped rib 11 at the outer circumferential edge, and warpage of the wafer itself and a fault (such as a fracture and chipping) caused during transfer can be prevented. The width of the ring-shaped rib 11 may be, for example, about 2 mm to 4 mm, although the width is adjustable for maintaining the strength.

A protective film 14 (first protective film) for protecting the back surface of the semiconductor wafer 1 is pasted on the back surface. The protective film 14 has a circular shape so as to cover the entire back surface of the semiconductor wafer 1. The protective film 14 is pasted along a part from the bottom surface of the concave portion 10 to the tilting surface 13 and the lower surface of the rib 11. In other words, the protective film 14 has an outer circumferential edge that bends so as to run on a step part formed by the concave portion 10.

A protective film 15 (second protective film) for protecting the outer circumferential edge of the semiconductor wafer 1 is pasted on the outer circumferential edge. More specifically, the protective film 15 is pasted so as to cover the outer circumferential edge of the protective film 14 and the entire outer circumference of the rib 11 including the upper and lower chamfered portions 12.

The protective film 14 is formed of a material such as polyester. The thickness of the protective film 14 is preferably equal to 30 μm to 100 μm. More preferably, the thickness of the protective film 14 is 50 μm. The protective film 14 has an adhesive layer (not shown) on its surface on the side in contact with the back surface of the semiconductor wafer 1. These descriptions are examples and do not limit the numerical values.

The protective film 15 is formed of a material such as polyolefin. The thickness of the protective film 15 is preferably equal to 80 μm to 180 μm. More preferably, the thickness of the protective film 15 is 130 μm. The protective film 15 is preferably thicker than the protective film 14. The protective film 15 has an adhesive layer (not shown) on its surface on the side in contact with the outer circumferential edge of the semiconductor wafer 1. These descriptions are examples and do not limit the numerical values.

By the way, in the semiconductor field in recent years, with diameter increases and thickness reduction of semiconductor wafers, the semiconductor wafers themselves are easily warped. Accordingly, a technology has been proposed which forms a ring-shaped rib by leaving the thickness of the outer circumferential part of a semiconductor wafer to increase rigidity of the entire wafer and suppress warpage, as in the manner described above.

According to a semiconductor device manufacturing method, a plating treatment is performed on one main surface side (front surface side) of a semiconductor wafer in one step of device formation on the surface. In this case, to prevent the plating treatment from being performed at a part that is not related to the device region, a protective film is pasted in advance on a predetermined part of the semiconductor wafer, as described above.

In the step of pasting the protective film, bubbles may be formed between the semiconductor wafer and the protective film. In the subsequent plating treatment, the semiconductor wafer and the protective film are exposed to a relatively high temperature environment. Therefore, there is a risk that the bubbles expand under the temperature and that a plating solution enters into the bubbles. As a result, it is assumed that a plated layer is formed even in an unnecessary part, which produces a product having unpreferable appearance.

Accordingly, in a conventional technology, after the protective film is pasted and before the plating treatment is performed, the protective film is heated. Thus, the adhesive layer of the protective film is softened, and the size of gaps between the bubbles and the like interposed between the protective film and the semiconductor wafer is reduced. As a result, the adhesion between the protective film and the semiconductor wafer is improved.

With reference to a comparison example in FIG. 3, a conventional heating step is now described. As shown in FIG. 3, a plurality of semiconductor wafers 1 on which the protective films 14 and 15 are pasted are accommodated within a box-shaped cassette C. At this time, the plurality of semiconductor wafers 1 are set up such that the thickness direction is oriented in the right-left direction (Y direction) and the semiconductor wafers 1 are aligned in the Y direction. The cassette C is inserted to a so-called batch oven furnace F, and the cassette C as a whole undergoes heating processing.

However, the over furnace F has an internal space that is greatly larger than the size of the cassette C and the semiconductor wafers 1. For that, uneven in-furnace temperatures easily occur. Because time is required until a stable in-furnace temperature is acquired, there is a risk that the throughput of the entire manufacturing process is influenced. Also, as described above, with increases of diameters of the semiconductor wafers 1, the size of the cassette C itself is increased, which may cause a problem that automatic transfer of the cassette C is difficult.

Accordingly, the present inventors have reached the present invention with focus on a method for effectively heating the protective films 14 and 15 pasted on the semiconductor wafer 1. More specifically, according to the embodiment, the first protective film 14 and the second protective film 15 pasted on the back surface and outer circumferential edge of the rib-shaped semiconductor wafer 1 are directly heated by a hot plate 2.

with reference to FIG. 4 and FIG. 5, a partial configuration of the semiconductor manufacturing apparatus 100 according to the embodiment is now described. It should be noted that the semiconductor manufacturing apparatus 100 is not limited to the configuration shown in FIG. 4 and FIG. 5 but can be changed as required.

As shown in FIG. 4 and FIG. 5, the semiconductor manufacturing apparatus 100 includes a transfer robot H and the hot plate 2. It should be noted that the semiconductor manufacturing apparatus 100 is not limited to the components but may include other components.

The transfer robot H has a plate-like body having a U-shape in plan view. The semiconductor wafer 1 is mounted on an upper surface of the transfer robot H, and the transfer robot H can suck and hold it. For example, the transfer robot H may have a suction hole for sucking and holding the semiconductor wafer 1. The transfer robot H can move to a desired position within the apparatus by a transfer mechanism, not shown. Thus, the semiconductor wafer 1 can be transferred to the predetermined position within the apparatus. The transfer robot H may apply other holding method, without limiting to the sucking and holding, for holding the semiconductor wafer 1. The transfer robot H may be a plate-like body having other shapes, without limiting to the plate-like body having a U-shape in plan view, in accordance with the transfer mechanism or the method for holding the semiconductor wafer 1.

The hot plate 2 has a disk-shaped base 20 internally containing a heater (not shown). The base 20 has a circular shape in plan view that is sufficiently larger than the outside diameter of the semiconductor wafer 1. It should be noted that the base 20 is not limited to have a circular shape but may have an arbitrary shape such as a square shape. The base 20 has an upper surface being a heating surface that can heat the semiconductor wafer 1 (the first protective film 14 and the second protective film 15). The temperature of the heating surface can be increased to a desired temperature by the heater. Resin coating for preventing sticking may be performed on the heating surface, details of which are described below.

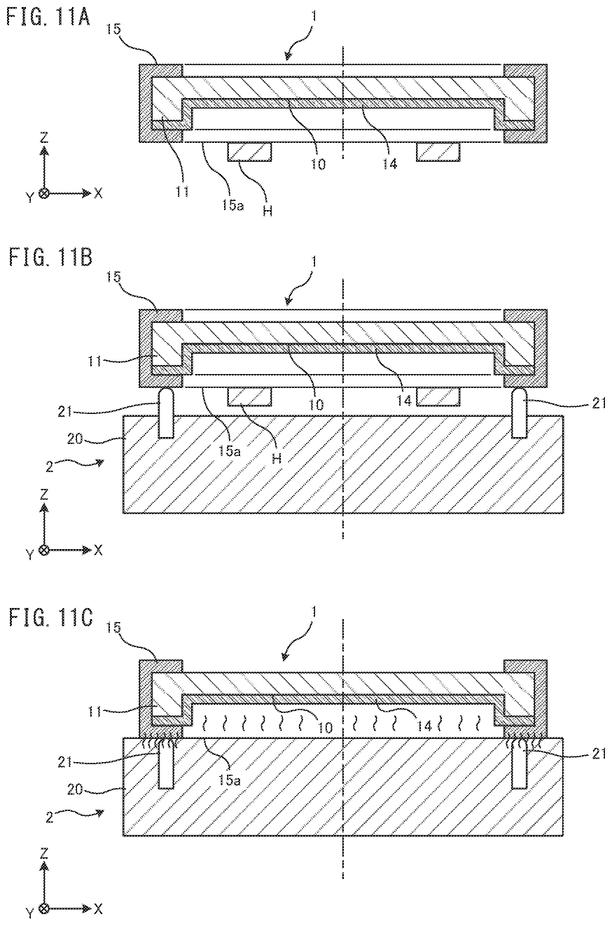

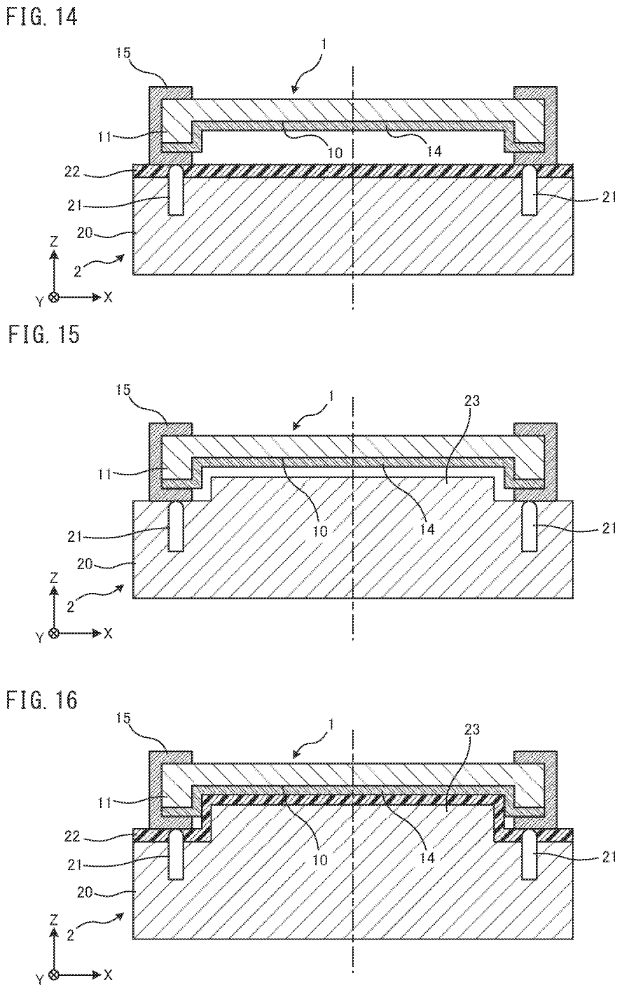

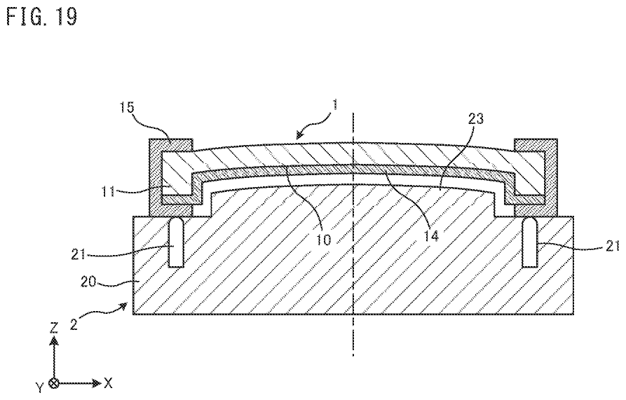

The hot plate 2 further has a forcing pin 21 that is retractable with respect to the heating surface. More specifically, the forcing pin 21 has a cylindrical axis extending in the Z direction. A plurality of (three in the embodiment) forcing pins 21 are disposed at equal angular intervals in the circumferential direction in plan view. The plurality of forcing pins 21 are disproportionately disposed on the outer circumferential side of the base 20 and, more specifically, are disposed at positions corresponding to a part immediately below the rib 11 of the semiconductor wafer 1. Each of the forcing pins 21 has an upper end that is rounded and is retractable in the Z direction with respect to the heating surface. The upper end of the forcing pin 21 can be abutted against the back surface side (the first protective film 14 and the second protective film 15) of the semiconductor wafer 1. The forcing pins 21 are shown in FIG. 5 for convenience of description although they do not exist in the cross-sectional view. Therefore, FIG. 5 does not limit the positions of the forcing pins 21, but the positions in the circumferential direction of the forcing pins 21 may be anywhere if they are immediately below the rib 11. The number of the provided forcing pins 21 can also be changed as required. The same is true for FIG. 11, FIG. 14 to FIG. 16, FIG. 18 and FIG. 19 which are described below.

According to the semiconductor manufacturing apparatus 100 configured in this way, the back surface of the semiconductor wafer 1 is disposed so as to face the heating surface of the hot plate 2 so that the first protective film 14 and the second protective film 15 can be directly heated by the hot plate 2 (see FIG. 11, which is described below). Thus, even when bubbles occur between the semiconductor wafer 1 and the protective films, the adhesive layers of the protective films are softened because of the temperature and the bubbles can be easily removed. In other words, the adhesion of the protective films to the semiconductor wafer 1 can be improved.

The hot plate 2 can reduce the time required until the temperature is stabilized at a desired temperature, compared with the case where the heating is performed in a conventional batch oven furnace F. Furthermore, with the hot plate 2, the automatic transfer that is difficult with the conventional batch oven furnace F can be realized by the transfer robot H. Therefore, the processing on the semiconductor wafer 1 can be performed efficiently with an improved throughput of the apparatus.

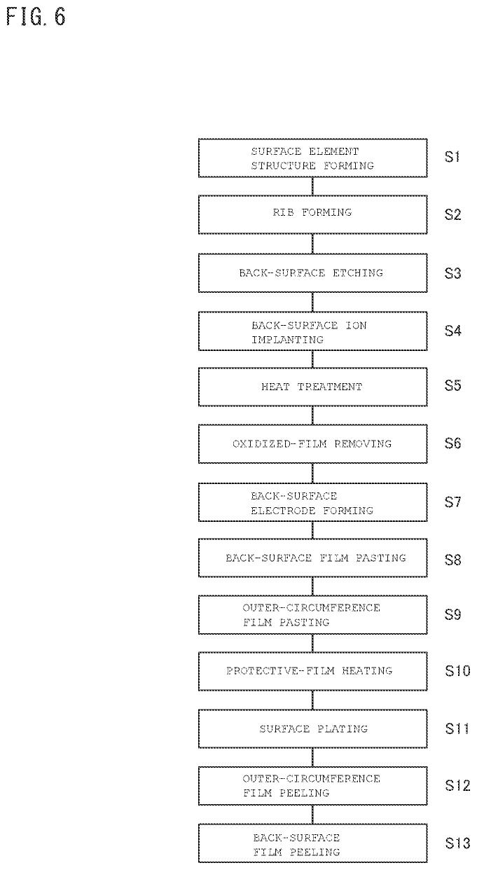

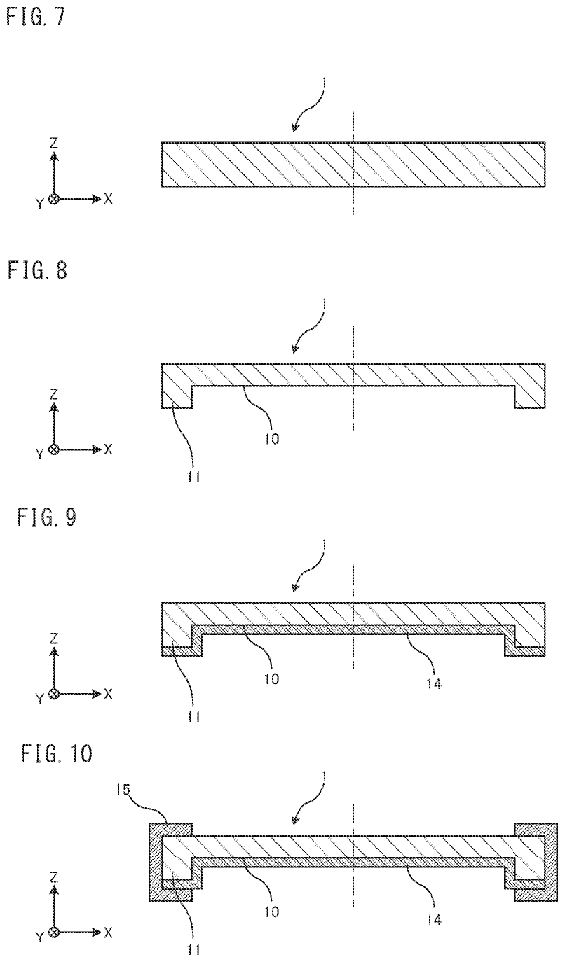

Next, with reference to FIG. 6 to FIG. 12, a semiconductor device manufacturing method according to the embodiment is described. FIG. 6 is a flowchart showing an example of the semiconductor device manufacturing method according to the embodiment. FIG. 7 to FIG. 12 are schematic diagrams each showing one step example of the semiconductor device manufacturing method of the embodiment. Particularly, FIGS. 11A to 11C show operation transition diagrams of work transfer in a protective-film heating step. It should be noted that the following semiconductor device manufacturing method is merely an example, is not limited to the configuration, but can be changed as required.

As shown in FIG. 6, the semiconductor device manufacturing method according to the embodiment includes:

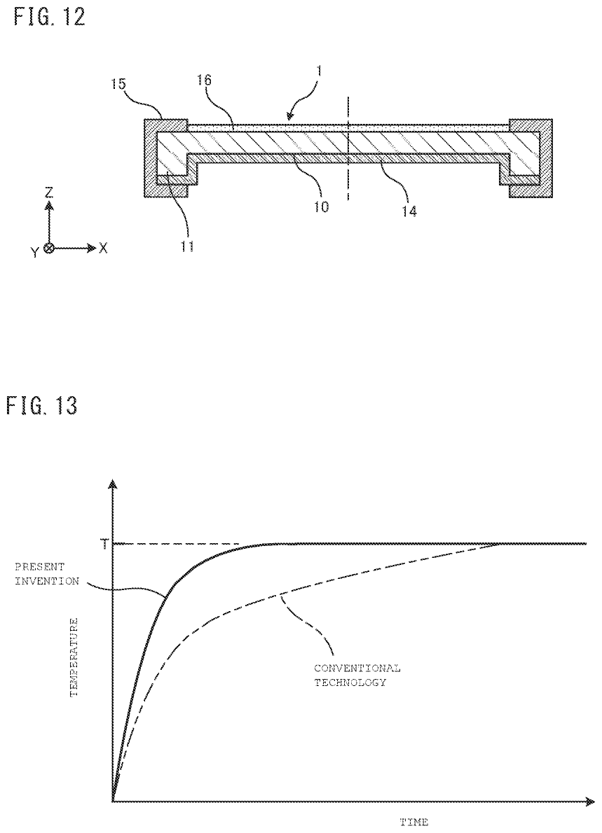

(1) a surface element structure forming step (step S1, see FIG. 7);
(2) a rib forming step (step S2, see FIG. 8);
(3) a back-surface etching step (step S3);
(4) a back-surface ion implanting step (step S4);
(5) a heat treatment step (step S5);
(6) an oxidized-film removing step (step S6);
(7) a back-surface electrode forming step (step S7);
(8) a back-surface film pasting step (step S8, see FIG. 9);
(9) an outer-circumference film pasting step (step S9, see FIG. 10);
(10) a protective-film heating step (step S10, see FIG. 11);
(11) a surface plating step (step S11, see FIG. 12);
(12) an outer-circumference film peeling step (step S12); and
(13) a back-surface film peeling step (step S13).
It should be noted that the order of these steps can be changed as required if no contradiction arises.

First, as shown in FIG. 7, in the surface element structure forming step, various element structures (not shown) are formed on a surface of the semiconductor wafer 1 having a substantially uniform thickness of, for example, about 700 μm. For example, element structures are formed up to an emitter electrode of front-surface element structures including a MOS gate (insulating gate including metal-oxide film-semiconductor) structure of, for example, a field-stop (FS) type IGBT. The emitter electrode may be a metallic film mainly containing, for example, aluminum (Al). The emitter electrode may be patterned in a region where semiconductor chips are to be formed. As the method for forming the element structures, an existing method is adopted. A plated layer is selectively formed in the surface plating step (S11), which is described below, on a surface of the emitter electrode.

Next, the rib forming step is performed. As shown in FIG. 8, in the rib forming step, a center of the back surface of the semiconductor wafer 1 is grinded, and the ring-shaped rib 11 having a larger thickness than the center is formed on an outer circumferential edge of the semiconductor wafer 1. The thickness of the remaining part of the grinded concave portion 10 may be, for example, about 100 μm. By reducing the thickness of the concave portion 10, the resistance component of the semiconductor substrate in the semiconductor device can be reduced.

Next, the back-surface etching step is performed. In the back-surface etching step, projections and depressions formed on the back surface of the semiconductor wafer 1 by, for example, the grinding in advance and damage caused on the back surface by the grinding are removed by etching. The method for removing the projections and depressions is not limited to the etching but can be any one of various methods. The amount of etching is, for example, about 20 μm. Thus, the damage caused by the grinding can be removed, and mechanical stress due to the damage caused by the grinding can be alleviated.

Next, the back-surface ion implanting step is performed. In the back-surface ion implanting step, ions (dopants) are implanted to the back surface of the semiconductor wafer 1. As the ion implanting method, an existing method is adopted. For example, ion implantation of n-type impurities for forming an n-type buffer layer and ion implantation of p-type impurities for forming p⁺ type collector layer may be performed sequentially.

Next, the heat treatment step is performed. In the heat treatment step, the semiconductor wafer 1 is heated at a predetermined temperature. Thus, the ions implanted in the semiconductor wafer 1 are activated. As the heating method, various methods can be adopted.

Next, the oxidized-film removing step is performed. In the oxidized-film removing step, a hardened layer (oxidized film) on the surface of the semiconductor wafer 1 is removed by, for example, etching. For the removal of the surface hardened layer, various methods can be adopted, without limiting to etching. More specifically, the surface hardened layer is, for example, a natural oxidized film formed on the surface layer of the semiconductor wafer 1 and may be removed with, for example, dilute hydrofluoric acid (HF).

Next, the back-surface electrode forming step is performed. In the back-surface electrode forming step, an electrode is formed on the back surface of the semiconductor wafer 1. The electrode is formed by a metallic film having a predetermined thickness and is formed by, for example, vapor deposition or sputtering. The electrode is formed by sequentially stacking, for example, an aluminum layer, a titanium layer, a nickel layer, and a gold layer.

Next, the back-surface film pasting step is performed. As shown in FIG. 9, in the back-surface film pasting step, the protective film 14 is pasted on the entire back surface of the semiconductor wafer 1. As described above, the entire surface of the concave portion 10 and the rib 11 are covered by the protective film 14. The pasting of the protective film 14 may be automatically performed by the apparatus or may be performed by human hands. The protective film 14 may be pasted in vacuum such that bubbles are not formed between the semiconductor wafer 1 and the protective film 14.

Next, the outer-circumference film pasting step is performed. As shown in FIG. 10, in the outer-circumference film pasting step, the protective film 15 is pasted so as to cover the outer circumferential edge of the protective film 14 and the outer circumference of the rib 11. At the outer circumferential edge of the semiconductor wafer 1, the upper and lower surfaces are sandwiched by the protective film 15. The outer circumferential edge of the protective film 14 is sandwiched between the semiconductor wafer 1 and the protective film 15. The pasting of the protective film 15 may be automatically performed by the apparatus or may be performed by human hands.

Next, the protective-film heating step is performed. As shown in FIG. 11, in the protective-film heating step, the semiconductor wafer 1 is first transferred to the hot plate 2 by the transfer robot H. The semiconductor wafer 1 on which the protective films 14 and 15 are pasted are sucked and held by the transfer robot H. More specifically, as shown in FIG. 11A, an upper surface of the transfer robot H is abutted against a lower surface 15a of the protective film 15 covering the rib 11, and the protective film 15 is sucked to the upper surface of the transfer robot H.

The transfer robot H transfers the semiconductor wafer 1 to a part immediately above the hot plate 2. The back surface of the semiconductor wafer 1 is disposed so as to face the heating surface of the hot plate 2. More specifically, as shown in FIG. 11B, in the hot plate 2, three forcing pins 21 project at a predetermined height from the upper surface (heating surface) of the base 20. The transfer robot H moves such that the outer circumferential edge (rib 11) of the semiconductor wafer 1 is positioned immediately above the forcing pins 21.

The transfer robot H is further adjusted to a height where the lower surface of the protective film 15 is abutted against the tips of the forcing pins 21. Then, the transfer robot H cancels the suction and holding of the semiconductor wafer 1, is adjusted to a height away from the lower surface 15a of the protective film 15, and moves away from the part under the semiconductor wafer 1. As shown in FIG. 4, because the transfer robot H has a U-shape in plan view and is disposed to extend between the forcing pins 21 in plan view, the transfer robot H does not interfere with the forcing pins 21.

Having described above the case where the rib 11 of the semiconductor wafer 1 is sucked and held for transfer by the transfer robot H in order to prevent a fault (such as a fracture and chipping) caused during the transfer of the rib-shaped semiconductor wafer 1, the semiconductor wafer 1 may be held by other methods. For example, the transfer robot H may have a counter bore, and the semiconductor wafer 1 may be mounted in the counter bore to hold it. Alternatively, a Bernoulli chuck may be used to hold the semiconductor wafer 1 from its front surface.

When the transfer robot H moves away from the part under the semiconductor wafer 1, the semiconductor wafer 1 is supported by the three forcing pins 21. After that, the three forcing pins 21 are retracted into the base 20. Thus, the semiconductor wafer 1 is moved downward so that, as shown in FIG. 11C, the lower surface 15a of the protective film 15 is brought into contact with the heating surface.

The heating surface of the hot plate 2 is warmed in advance to a desired temperature by the heater. For example, the heating surface is heated to a temperature of about 70° C. to 80° C. Thus, from the instance when the semiconductor wafer 1 touches the heating surface, the protective films 14 and 15 can be directly heated.

The protective films 14 and 15 are softened by being heated. Thus, even if bubbles are formed between the semiconductor wafer 1 and the protective films 14 and 15, the bubbles are removed so that the adhesion with each other can be improved. A predetermined gap is provided between the protective film 14 and the heating surface in the part corresponding to the concave portion 10 of the semiconductor wafer 1. However, the gap does not have a size having an influence on the heating of the protective film 14, the heat of the heating surface can be directly transmitted to the protective film 14. The gap between the lower surface of the protective film 14 and the heating surface may have a size of, for example, about 100 μm.

Next, the surface plating step (which may be simply called a plating step) is performed. As shown in FIG. 12, in the surface plating step, a plating treatment is performed on the surface of the semiconductor wafer. More specifically, a plated layer 16 having a predetermined thickness is formed on the surface of the semiconductor wafer 1. The plated layer 16 is formed on the entire surface of the emitter electrode on the upper surface of the semiconductor wafer 1 on which the protective films 14 and 15 are not pasted. The plated layer 16 may be a layer acquired by providing a nickel plated layer and then stacking a gold plated layer on the entire surface of the nickel plated layer. The plated layer 16 is formed by being exposed in an electroless plating path having a temperature of, for example, about 70° C. to 80° C. for 40 to 50 minutes.

Next, the outer-circumference film peeling step is performed. In the outer-circumference film peeling step, the protective film 15 is peeled from the semiconductor wafer 1. The peeling of the protective film 15 may be performed automatically by the apparatus or may be performed by human hands.

Next, the back-surface film peeling step is performed. In the back-surface film peeling step, the protective film 14 is peeled from the semiconductor wafer 1. The peeling of the protective film 14 may be performed automatically by the apparatus or may be performed by human hands.

Because the subsequent steps have details not directly related to the present invention, description is omitted.

In this way, according to the embodiment, after the protective films 14 and 15 are pasted on the semiconductor wafer 1 having the rib 11, the protective films 14 and 15 are directly heated by the heating surface of the hot plate 2. Thus, a good semiconductor device can be manufactured by removing the bubbles in the protective films 14 and 15 in a short period of time and without forming an unnecessary plated layer in the subsequent plating step.

With reference to FIG. 13, rises of the temperature for heating the protective films are now described by comparing the present invention and a conventional technology. FIG. 13 has a horizontal axis indicating time and a vertical axis indicating temperature. The shown solid line in the graph indicates an example of the present invention where the temperature is a temperature of the heating surface, for example. The shown chain double-dashed line in the graph indicates an example of a conventional technology, and the temperature is an in-furnace temperature.

As shown in FIG. 13, conventionally, for example, about 10 minutes have been required for increasing the temperature to a target heating temperature T. Also, conventionally, an additional time of 10 to 20 minutes has been actually required for processing the semiconductor wafer 1 after the target heating temperature T is acquired. This has had an influence on the takt time for the apparatus. On the other hand, according to the present invention, the time for acquiring the target temperature T can be greatly reduced to two to three minutes. Furthermore, the time for processing the semiconductor wafer 1 can be actually reduced to one to two minutes after the target heating temperature T is acquired. As a result, the throughput of the entire apparatus can be improved. In this way, by using the hot plate 2, the rise time until the target heating temperature T is acquired can be reduced, and the takt time for the entire heating step can be reduced.

For applying the heating step of the protective films 14 and 15 of the present invention, examples of parameters of the semiconductor wafer 1 and the protective films 14 and 15 are as follows. For example, as shown in FIG. 2, the semiconductor wafer 1 has a thickness D1 of 725 μm. The semiconductor wafer 1 at the part where the concave portion 10 is provided has a remaining thickness D2 of 100 μm. The concave portion 10 has a depth D3 of 625 μm. Here, D1=D2+D3.

A distance D4 from the upper surface of the semiconductor wafer 1 to the lower surface of the protective film 15 is equal to 905 μm. A distance D5 from the bottom surface of the concave portion 10 to the lower surface of the protective film 15 is equal to 805 μm. A distance D6 from the lower surface of the protective film 14 positioned immediately below the concave portion 10 to the lower surface of the protective film 15 is equal to 755 μm. It should be noted that these descriptions do not limit the numerical values.

Although various materials are selectable for the protective films 14 and 15, the protective film 15 is preferably made of a material having more flexibility than the protective film 14, for example. This is because the protective film 15 that is easily bendable is preferable since the protective film 15 is bent to a U-shape in cross-sectional view so as to cover the entire outer circumference of the rib 11. The adhesive layers of the protective films 14 and 15 may be made of a material that changes its adhesion when they are irradiated with an ultraviolet (UV) ray or a material that changes its adhesion in accordance with the temperature.

Next, with reference to FIG. 14 to FIG. 19, variation examples are described. FIG. 14 to FIG. 19 are schematic diagrams of hot plates according to the variation examples.

Having described that, according to the aforementioned embodiment, the upper surface of the base 20 is the heating surface that directly touches the lower surface (protective film 15) of the semiconductor wafer 1, the present invention is not limited to the configuration. For example, as shown in FIG. 14, a resin film 22 having a predetermined thickness may be formed on the upper surface of the base 20, and at least a part of the protective film 15 may be brought into contact with the resin film 22. In this case, the upper surface of the resin film 22 is the heating surface. The resin film 22 is made of, for example, a fluorinated resin. Because of the formed resin film 22, the protective film 15 can be suppressed from sticking to the hot plate 2. The resin film 22 preferably has a thickness of 20 μm to 300 μm. More preferably, the resin film 22 has a thickness of 20 μm to 50 μm. Within this range, the heat conductivity can be secured, and, at the same time, the sticking of the protective film 15 can be effectively prevented.

As shown in FIG. 15, the heating surface of the hot plate 2 (the upper surface of the base 20) may have a circular convex portion 23 in a part corresponding to the concave portion 10 of the semiconductor wafer 1. The circular convex portion 23 has an outside diameter smaller than the diameter on the inner circumference side of the rib 11 and projects with a predetermined thickness in the Z direction. The circular convex portion 23 preferably has a size that fits within the concave portion 10 when the semiconductor wafer 1 is mounted to the hot plate 2. With this configuration, the gap between the lower surface of the protective film 14 and the heating surface can be filled by the circular convex portion 23, and the heating surface can get closer to the lower surface of the protective film 14. The circular convex portion 23 may have a height with which the protective film 14 and the protective film 15 are in contact with the heating surface. As a result, the protective film 14 can be effectively warmed. It should be noted that the upper surface of the circular convex portion 23 may be in contact with the protective film 14. For mounting the semiconductor wafer 1 to the hot plate 2, the circular convex portion 23 functions as a positioning member with respect to the concave portion 10.

As shown in FIG. 16, the resin film 22 may be formed on the entire upper surface of the base 20 having the circular convex portion 23. With this configuration, the effect of the heating of the protective film 14 can be increased, and, at the same time, the sticking of the protective film 14 can be suppressed.

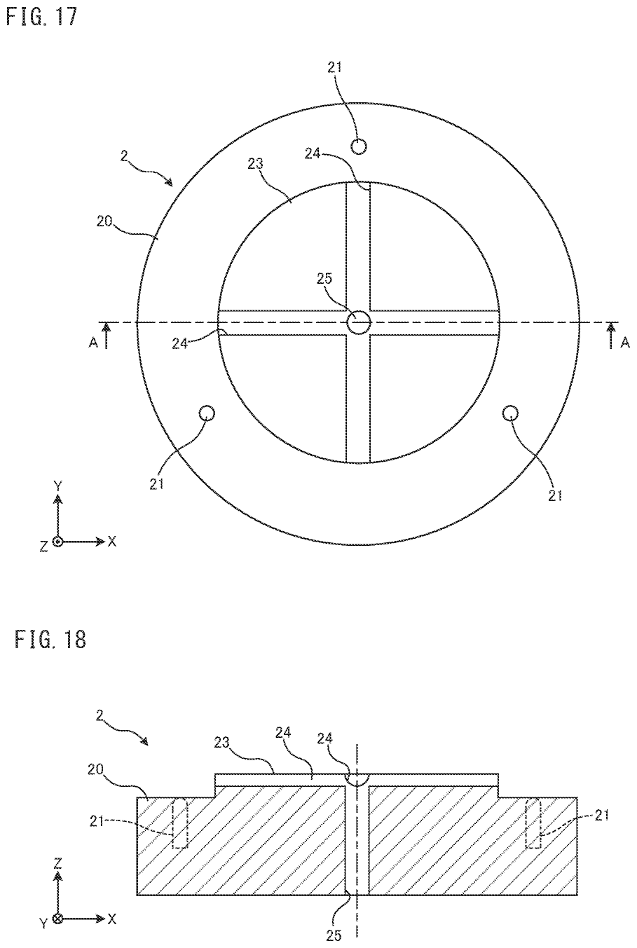

As shown in FIG. 17 and FIG. 18, in a case where the upper surface of the base 20 has the circular convex portion 23, the hot plate 2 may have a groove 24 on the upper surface of the circular convex portion 23 and a communicating hole 25 that communicates with the groove 24. The communicating hole 25 extends through the center of the base 20 in the Z direction. The communicating hole 25 may have a lower end connecting to a suction source, not shown. A plurality of grooves 24 extend radially from the communicating hole 25 toward radial outside. Each of the grooves 24 preferably has a semicircular cross-section viewed from the direction of extension (radial direction). With the grooves 24 and the communicating hole 25, an air escape can be secured between the concave portion 10 and the circular convex portion 23 when the semiconductor wafer 1 is mounted to the hot plate 2. The grooves 24 and the communicating hole 25 function as an air escape also when the semiconductor wafer 1 is pushed up by the forcing pins 21 after heated so that the operation for pushing up the semiconductor wafer 1 can be realized by preventing application of stress to the concave portion 10.

Although the use of the rib-shaped semiconductor wafer 1 suppresses its warpage as a whole according to the aforementioned embodiment, a case where warpage of the semiconductor wafer 1 itself slightly occurs is still conceivable. For example, as shown in FIG. 19, a case is conceivable where the central part that is thin of the semiconductor wafer 1 is curved so as to project upward with the concave portion 10 facing the lower surface. In this case, preferably, the upper surface (heating surface) of the circular convex portion 23 facing the curved part also has a spherical shape having a convex-shaped upper part. By providing the heating surface formed in accordance with (by following) the warpage shape of the semiconductor wafer 1, the gap between the heating surface and the protective film 14 can be reduced as much as possible to further increase the heating effect. In this case, the resin film 22 may be formed on the upper surface of the circular convex portion 23.

In this way, having described the embodiment and variation examples, all or a part of the embodiment and the variation examples may be combined as other embodiments.

Embodiments are not limited to the aforementioned embodiment and variation examples, but various changes, replacements and variations can be made thereto without departing from the spirit and scope of the technical idea. Furthermore, if the technical idea can be realized by a different method with an advance of the technology or a different technology derived therefrom, the technical idea can be implemented by using the method. Therefore, the claims cover all embodiments that can be included within the scope of the technical idea.

Characteristic points according to the aforementioned embodiments are organized below.

A semiconductor device manufacturing method according to the aforementioned embodiment includes a rib forming step of forming a ring-shaped rib at an outer circumferential edge of a semiconductor wafer by grinding a center of a back surface of the semiconductor wafer, the rib having a larger thickness than a thickness of the center of the semiconductor wafer, a back-surface film pasting step of pasting a first protective film on the back surface of the semiconductor wafer, an outer-circumference film pasting step of pasting a second protective film so as to cover an outer circumferential edge of the first protective film and an outer circumference of the rib, a heating step of positioning the back surface of the semiconductor wafer so as to face a heating surface of a hot plate and directly heating the first protective film and the second protective film by using the hot plate, and a plating step of performing a plating treatment on a surface of the semiconductor wafer.

In the semiconductor device manufacturing method according to the aforementioned embodiment, the heating surface of the hot plate has thereon a resin film having a predetermined thickness, and, in the heating step, at least a part of the second protective film is in contact with the resin film.

In the semiconductor device manufacturing method according to the aforementioned embodiment, the resin film is formed of a fluorinated resin.

In the semiconductor device manufacturing method according to the aforementioned embodiment, the heating surface of the hot plate has a circular convex portion having a smaller outside diameter than a diameter on an inner circumference side of the rib, and, in the heating step, the semiconductor wafer is mounted to the heating surface of the hot plate such that the circular convex portion fits into an inner side of the rib.

In the semiconductor device manufacturing method according to the aforementioned embodiment, the hot plate has a groove on an upper surface of the circular convex portion, and a communicating hole that communicates with the groove.

In the semiconductor device manufacturing method according to the aforementioned embodiment, the semiconductor wafer is curved such that an upper part of the semiconductor wafer has a projection shape, and the heating surface of the hot plate has a spherical shape having a convex-shaped upper part.

A hot plate according to the aforementioned embodiment is a hot plate that heats a first protective film and a second protective film, the first protective film and second protective film being pasted on a semiconductor wafer. The semiconductor wafer has a ring-shaped rib at an outer circumferential edge of the semiconductor wafer, the rib is formed by grinding a center of a back surface of the semiconductor wafer, and the rib has a larger thickness than a thickness of the center of the semiconductor wafer, the first protective film is pasted on the back surface of the semiconductor wafer, the second protective film is pasted so as to cover an outer circumferential edge of the first protective film and an outer circumference of the rib, and the hot plate has a heating surface, the back surface of the semiconductor wafer is positioned so as to face the heating surface, and the heating surface directly heats the first protective film and the second protective film.

In the hot plate according to the aforementioned embodiment, the heating surface has thereon a resin film having a predetermined thickness, and at least a part of the second protective film is heated in contact with the resin film.

In the hot plate according to the aforementioned embodiment, the resin film is formed of a fluorinated resin.

In the hot plate according to the aforementioned embodiment, the heating surface has a circular convex portion having a smaller outside diameter than a diameter on an inner circumference side of the rib, and the semiconductor wafer is mounted to the heating surface such that the circular convex portion fits into an inner side of the rib.

In the hot plate according to the aforementioned embodiment, the hot plate has a groove on an upper surface of the circular convex portion, and a communicating hole that communicates with the groove.

In the hot plate according to the aforementioned embodiment, the semiconductor wafer is curved such that an upper part of the semiconductor wafer has a projection shape, and the heating surface has a spherical shape having a convex-shaped upper part.

In the hot plate according to the aforementioned embodiment, the hot plate has a forcing pin that is positioned immediately below the rib and is retractable with respect to the heating surface.

### INDUSTRIAL APPLICABILITY

As described above, the present invention has effects that adhesion of protective films to a semiconductor wafer can be improved, and a throughput can be improved, and is particularly useful for a semiconductor device manufacturing method and a hot plate to be used therein.

### REFERENCE SIGNS LIST

100 semiconductor manufacturing apparatus
1 semiconductor wafer
2 hot plate
10 concave portion
11 rib
12 chamfered portion
13 tilting surface
14 first protective film
15 second protective film
15a lower surface of the second protective film
16 plated layer
20 base
21 forcing pin
22 resin film
23 circular convex portion
24 groove
25 communicating hole

What is claimed is:

1. A semiconductor device manufacturing method comprising:
forming a ring-shaped rib at an outer circumferential edge of a semiconductor wafer by grinding a center of a back surface of the semiconductor wafer, so that the rib has a thickness greater than a thickness of the center of the semiconductor wafer;
pasting a first protective film on the back surface of the semiconductor wafer;
pasting a second protective film so as to cover an outer circumferential edge of the first protective film and an outer circumference of the rib;
positioning the back surface of the semiconductor wafer so as to face a heating surface of a hot plate and directly heating the first protective film and the second protective film by using the hot plate; and
performing a plating treatment on a surface of the semiconductor wafer.

2. The semiconductor device manufacturing method according to claim 1, wherein
the heating surface of the hot plate has a resin film thereon, and
the directly heating the first protective film and the second protective film includes contacting at least a part of the second protective film with the resin film.

3. The semiconductor device manufacturing method according to claim 2, wherein the resin film contains a fluorinated resin.

4. The semiconductor device manufacturing method according to claim 1, wherein
the heating surface of the hot plate has a circular convex portion having an outer diameter smaller than a diameter of the rib at an inner circumference side, and
the directly heating the first protective film and the second protective film includes mounting the semiconductor wafer to the heating surface of the hot plate such that the circular convex portion fits into an inner side of the rib.

5. The semiconductor device manufacturing method according to claim 4, wherein
the hot plate has
a groove on an upper surface of the circular convex portion, and
a communicating hole formed in the groove, and penetrating through the hot plate.

6. The semiconductor device manufacturing method according to claim 4, wherein
the semiconductor wafer is curved such that an upper part of the semiconductor wafer has a projection shape, and
the heating surface of the hot plate has a spherical shape having a convex-shaped upper part that corresponds to the projection shape of the upper part of the semiconductor wafer.

7. A hot plate used for the semiconductor device manufacturing method according to claim 1, the hot plate comprising:
a heater disposed therein; and
the heating surface through which the hot plate directly heats the first protective film and the second protective film.

8. The hot plate according to claim 7, further comprising
a resin film formed on the heating surface, for preventing at least a part of the second protective film from directly contacting the heating surface.

9. The hot plate according to claim 8, wherein the resin film contains a fluorinated resin.

10. The hot plate according to claim 7, wherein
the heating surface has a circular convex portion having an outer diameter smaller than a diameter at an inner circumference side of the rib, and
the semiconductor wafer is mounted to the heating surface such that the circular convex portion fits into an inner side of the rib.

11. The hot plate according to claim 10, further comprising
a groove on an upper surface of the circular convex portion, and
a communicating hole formed in the groove and penetrating through the hot plate.

12. The hot plate according to claim 10, wherein
the semiconductor wafer is curved such that an upper part of the semiconductor wafer has a projection shape, and
the heating surface has a spherical shape having a convex-shaped upper part that corresponds to the projection shape of the upper part of the semiconductor wafer.

13. The hot plate according to claim 7, further comprising a forcing pin positioned immediately below the rib for pushing the semiconductor wafer away from the heating surface.
